(19) United States
(12) Patent Application Publication
(10) Pub. No.: US 2025/0144746 A1
(43) Pub. Date: May 8, 2025

(54) LASER ABLATION APPLICATIONS FOR ELECTROSTATIC CHUCKS

(71) Applicant: ENTEGRIS, INC., Billerica, MA (US)

(72) Inventors: Doruk Yener, Bedford, MA (US); Jakub Rybczynski, Arlington, MA (US); Isaac J. Parker, Dover, NH (US); Nilesh Gunda, North Chelmsford, MA (US); Christopher J. Yannetta, Weatherford, TX (US); Supil Raina, Fort Worth, TX (US); Chandrasekaran Venkatraman, Tyngsboro, MA (US)

(21) Appl. No.: 18/900,625

(22) Filed: Sep. 27, 2024

Related U.S. Application Data
(60) Provisional application No. 63/547,495, filed on Nov. 6, 2023.

(51) Int. Cl. B23K 26/40; B23K 101/36

(52) U.S. Cl. CPC B23K 26/40; B23K 2101/36

(57) ABSTRACT

Electrostatic chucks and methods for forming electrostatic chucks are provided. A method comprises obtaining a substrate comprising an etch resistant coating layer; ablating, with a laser, the etch resistant coating layer so as to remove at least a portion of the etch resistant coating layer so as to provide one or more exposed portions of the substrate; and forming an electrostatic chuck, wherein, when measuring an electrical resistance across the one or more exposed portions of the substrate between two metallized portions, the electrostatic chuck exhibits an electrical isolation of 300 GΩ or more. An electrostatic chuck comprises a substrate having at least one etch resistant coating layer comprising a laser ablated pattern, wherein the laser ablated pattern comprises one or more exposed portions of the substrate spanning distances of at least 0.5 mm.

### CROSS-REFERENCE TO RELATED APPLICATION

This application claims the benefit of and priority to U.S. Provisional Application No. 63/547,495 filed on Nov. 6, 2023, which is incorporated herein by reference in its entirety for all purposes.

### FIELD

This disclosure relates to electrostatic chucks. More particularly, this disclosure relates to methods of forming electrostatic chucks using laser ablation and electrostatic chucks having laser ablated patterns.

### BACKGROUND

Current electrostatic chuck metallization and embossing processes use photolithography which involves multiple masking and etching steps utilizing a variety of chemicals leading to higher costs and longer lead times. Controllable and affordable methods for producing and embossing electrostatic chucks is an ongoing challenge.

### SUMMARY

This disclosure relates to methods of forming electrostatic chucks using laser ablation and electrostatic chucks having laser ablated patterns.

Some embodiments relate to methods of forming electrostatic chucks. In some embodiments, the methods comprise obtaining a substrate comprising an etch resistant coating layer; ablating, with a laser, the etch resistant coating layer so as to remove at least a portion of the etch resistant coating layer so as to provide one or more exposed portions of the substrate; and forming an electrostatic chuck, wherein, when measuring an electrical resistance across the one or more exposed portions of the substrate between two metallized portions, the electrostatic chuck exhibits an electrical isolation of 300 GΩ or more.

Some embodiments relate to the methods of forming electrostatic chucks. In some embodiments, the methods comprise obtaining a substrate comprising a metallized layer; ablating, with a laser, the metallized layer so as to remove at least a portion of the metallized layer so as to provide one or more exposed portions of the substrate; and forming an electrostatic chuck, wherein, when measuring an electrical resistance across the one or more exposed portions of the substrate between two metallized portions, the electrostatic chuck exhibits an electrical isolation of 300 GΩ or more.

Some embodiments relate to electrostatic chucks. In some embodiments, the electrostatic chucks comprise a substrate having at least one etch resistant coating layer comprising a laser ablated pattern, wherein the laser ablated pattern comprises one or more exposed portions of the substrate spanning distances of at least 0.5 mm.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method of forming an electrostatic chuck, according to some embodiments.

FIG. 2 is a schematic diagram of a method of forming an electrostatic chuck, according to some embodiments.

FIG. 3 includes tables summarizing test results obtained from the evaluation of laser-ablated samples provided in accordance with some embodiments.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION

Among those benefits and improvements that have been disclosed, other objects and advantages of this disclosure will become apparent from the following description taken in conjunction with the accompanying figures. The detailed description and the drawings, which are not necessarily to scale, depict illustrative embodiments and are not intended to limit the scope of the disclosure. The illustrative embodiments depicted are intended only as exemplary. Selected features of any illustrative embodiment may be incorporated into an additional embodiment unless clearly stated to the contrary.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise.

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Some embodiments relate to electrostatic chucks and methods of forming an electrostatic chuck. In some embodiments, the methods disclosed herein employ the use of laser ablation to form electrostatic chucks having complex and intricate metal electrode patterns, which heretofore have not been realized. For example, the methods disclosed herein may be employed to form precisely patterned metal traces with improved patterns and geometry, as well as tight spacing and widths. As another example, the methods disclosed herein may be employed with respect to materials that are difficult to etch and/or cannot be etched, while also reducing fabrication time. As disclosed herein, these methods can be used to fabricate electrostatic chucks exhibiting improved performance and function, among other things.

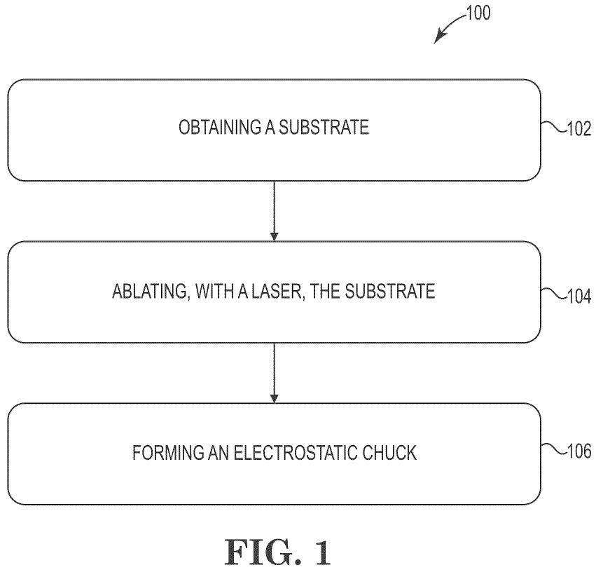

FIG. 1 is a flowchart of a method 100 for forming an electrostatic chuck, according to some embodiments. In some embodiments, the method 100 for forming an electrostatic chuck may include one or more of the following steps: a step 102 of obtaining a substrate, a step 104 of ablating, with a laser, the substrate, and a step 106 of forming an electrostatic chuck. In some embodiments, when measuring an electrical resistance across the one or more exposed portions of the substrate between two metallized portions located within the same horizontal plane, the electrostatic chuck displays an electrical isolation of 300 GΩ or more.

According to some embodiments, the method 100 of forming an electrostatic chuck includes obtaining a substrate having an etch resistant coating layer disposed thereon (block 102). In some embodiments, the method further includes ablating the etch resistant coating layer with a laser (block 104). The step 104 of ablating the etch resistance coating layer includes removing at least a portion of the etch resistant coating layer so as to provide one or more exposed portions of the underlying substrate.

Some embodiments of this disclosure provide for a method of forming an electrostatic chuck including obtaining a substrate having a metallized layer disposed thereon (block 102). In some embodiments, the metallized layer is ablated with a laser (block 104). In some embodiments, ablating the metallized layer with a laser includes removing at least a portion of the metallized layer so as to provide one or more exposed portions of the underlying substrate.

At step 102, in some embodiments, the method comprises obtaining a substrate including an etch resistant layer and/or a metallized layer. In some embodiments, the substrate includes at least one of a dielectric layer, a metallized layer, an etch resistant layer, a polymeric bonding layer, an insulator layer or any combination thereof. In some embodiments, the substrate includes a dielectric layer and an etch resistant layer located on the dielectric layer. In some embodiments, the substrate includes a dielectric layer and a metallized layer located on the dielectric layer. In some embodiments, the etch resistant layer directly contacts the dielectric layer. In some embodiments, the metallized layer directly contacts the dielectric layer. In some embodiments, the substrate is bonded to an insulator layer. In some embodiments, the substrate is bonded to an insulator layer via a polymeric bonding layer. In some embodiments, the substrate is bonded to an insulator layer via an adhesive layer. In some embodiments, the dielectric layer is located between the metallized layer and the etch resistant layer. In some embodiments, when the substrate is bonded to an insulator layer, the metallized layer is located between the dielectric layer and the polymeric bonding layer.

In some embodiments, the substrate includes, but is not limited to, ceramic, alumina, zirconia, aluminum-nitride, aluminum-oxy-nitride, silicon-nitride, silicon-oxide, silicon-carbide, silicon-oxy-nitride, silicon-carbo-nitride, tungsten-carbide, molybdenum-disilicide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combinations thereof. In some embodiments, the substrate includes ceramic. In some embodiments, the substrate includes alumina. In some embodiments, the substrate includes zirconia. In some embodiments, the substrate comprises aluminum-nitride. In some embodiments, the substrate includes aluminum-oxy-nitride. In some embodiments, the substrate includes silicon-nitride. In some embodiments, the substrate includes silicon-oxide. In some embodiments, the substrate includes silicon-carbide. In some embodiments, the substrate includes silicon-oxy-nitride. In some embodiments, the substrate includes silicon-carbo-nitride. In some embodiments, the substrate includes tungsten-carbide. In some embodiments, the substrate includes molybdenum-disilicide. In some embodiments, the substrate includes titanium-oxide. In some embodiments, the substrate includes hafnium silicate. In some embodiments, the substrate includes zirconium silicate. In some embodiments, the substrate includes zirconium silicate. In some embodiments, the substrate includes hafnium dioxide. In some embodiments, the substrate includes strontium dioxide. In some embodiments, the substrate includes scandium dioxide. In some embodiments, the substrate includes zirconium dioxide. In some embodiments, the substrate includes chromium oxide. In some embodiments, the substrate includes yttrium oxide. In some embodiments, the substrate includes iron oxide. In some embodiments, the substrate includes barium oxide. In some embodiments, the substrate includes barium titanate. In some embodiments, the substrate includes tantalum oxide.

In some embodiments, the etch resistant layer includes, but is not limited to, at least one of silicon carbide, diamond, carbon, yttrium oxide, aluminum oxide, or any combinations thereof. In some embodiments, the etch resistant layer includes silicon carbide. In some embodiments, the etch resistant layer includes yttrium oxide. In some embodiments, the etch resistant layer includes aluminum oxide. In some embodiments, the etch resistant layer includes diamond.

In some embodiments, the etch resistant layer is a coating. In some embodiments, the etch resistant layer is a deposited layer. In some embodiments, the etch resistant layer is deposited via one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the metallized layer includes, but is not limited to, aluminum, tungsten, nickel, stainless steel, silver, gold, tantalum, platinum, palladium, cobalt, titanium, copper, molybdenum, silicon, or any combinations thereof. In some embodiments, the metallized layer includes aluminum. In some embodiments, the metallized layer includes tungsten. In some embodiments, the metallized layer includes nickel. In some embodiments, the metallized layer includes stainless steel. In some embodiments, the metallized layer includes silver. In some embodiments, the metallized layer includes gold. In some embodiments, the metallized layer includes tantalum. In some embodiments, the metallized layer includes platinum. In some embodiments, the metallized layer includes palladium. In some embodiments, the metallized layer includes cobalt. In some embodiments, the metallized layer includes titanium. In some embodiments, the metallized layer includes copper. In some embodiments, the metallized layer includes molybdenum. In some embodiments, the metallized layer includes silicon.

The etch resistant layer can have a thickness of 0.1 μm to 50 μm, or any range or subrange between 0.1 μm and 50 μm. In some embodiments, the etch resistant layer has a thickness of 0.1 μm to 45 μm, 0.1 μm to 40 μm, 0.1 μm to 35 μm, 0.1 μm to 30 μm, 0.1 μm to 25 μm, 0.1 μm to 20 μm, 0.1 μm to 15 μm, 0.1 μm to 10 μm, 0.1 μm to 9 μm, 0.1 μm to 8 μm, 0.1 μm to 7 μm, 0.1 μm to 6 μm, 0.1 μm to 5 μm, 0.1 μm to 4 μm, 0.1 μm to 3 μm, 0.1 μm to 2 μm, 0.1 μm to 1 μm, 5 μm to 50 μm, 10 μm to 50 μm, 15 μm to 50 μm, 20 μm to 50 μm, 25 μm to 50 μm, 30 μm to 50 μm, 35 μm to 50 μm, 40 μm to 50 μm, or 45 μm to 50 μm.

The metallized layer can have a thickness of 0.1 μm to 50 μm, or any range or subrange between 0.1 μm and 50 μm. In some embodiments, the metallized layer has a thickness of 0.1 μm to 45 μm, 0.1 μm to 40 μm, 0.1 μm to 35 μm, 0.1 μm to 30 μm, 0.1μ m to 25 μm, 0.1 μm to 20 μm, 0.1 μm to 15 μm, 0.1 μm to 10 μm, 0.1 μm to 9 μm, 0.1 μm to 8 μm, 0.1 μm to 7 μm, 0.1 μm to 6 μm, 0.1 μm to 5 μm, 0.1 μm to 4 μm, 0.1 μm to 3 μm, 0.1 μm to 2 μm, 0.1 μm to 1 μm, 5 μm to 50 μm, 10 μm to 50 μm, 15 μm to 50 μm, 20 μm to 50 μm, 25 μm to 50 μm, 30 μm to 50 μm, 35 μm to 50 μm, 40 μm to 50 μm, or 45 μm to 50 μm. In some embodiments, the metallized layer has a thickness of 0.7 μm to 1.5 μm, or any range or subrange between 0.7 μm to 1.5 μm. For example, in some embodiments, the metallized layer has a thickness of 0.8 μm to 1.5 μm, 0.9 μm to 1.5 μm, 1 μm to 1.5 μm, 1.1 μm to 1.5 μm, 1.2 μm to 1.5 μm, 1.3 μm to 1.5 μm, 1.4 μm to 1.5 μm, 0.7 μm to 1.4 μm, 0.7 μm to 1.3 μm, 0.7 μm to 1.2 μm, 0.7 μm to 1.1 μm, 0.7 μm to 1 μm, 0.7 μm to 0.9 μm, or 0.7 μm to 0.8 μm.

At step 104, in some embodiments, the method includes ablating, with a laser, the substrate having an etch resistant layer and/or a metallized layer. In some embodiments, the method includes ablating, with a laser, the etch resistant layer to remove at least a portion of the etch resistant layer and obtain one or more exposed portions of the substrate. In some embodiments, the method includes ablating, with a laser, the metallized layer to remove at least a portion of the metallized layer and obtain one or more exposed portions of the substrate. In some embodiments, the ablating step 104 includes applying a laser to the substrate having the etch resistant layer and/or the metallized layer. In some embodiments, the ablating step 104 includes exposing the substrate having the etch resistant layer and/or the metallized layer to the laser. In some embodiments, the ablating step 104 includes removing at least a portion of the etch resistant layer and/or the metallized layer from substrate to expose a at least a portion of the underlying substrate. In some embodiments, the ablating step 104 includes setting parameters for a device producing the laser.

In some embodiments, the laser used in the ablating step 104 can include an ultra-violet nanosecond (UV ns) laser, an infra-red nanosecond (IR ns) laser, an infra-red picosecond (IR ps) laser, a green laser, or any combination thereof. In some embodiments, the laser includes an UV ns laser. In some embodiments, the laser includes an IR ns laser. In some embodiments, the laser includes an IR ps laser. In some embodiments, the laser includes a green laser.

In some embodiments, the laser used in ablating step 104 is applied at a rate of 0.5 mm²/s to 8.5 mm²/s, or any range or subrange between 0.5 mm²/s to 8.5 mm²/s. For example, in some embodiments, the laser is applied at a rate of 0.5 mm²/s to 8.5 mm²/s, 1 mm²/s to 8.5 mm²/s, 1.5 mm²/s to 8.5 mm²/s, 2 mm²/s to 8.5 mm²/s, 2.5 mm²/s to 8.5 mm²/s, 3 mm²/s to 8.5 mm²/s, 3.5 mm²/s to 8.5 mm²/s, 4 mm²/s to 8.5 mm²/s, 4.5 mm²/s to 8.5 mm²/s, 5 mm²/s to 8.5 mm²/s, 5.5 mm²/s to 8.5 mm²/s, 6 mm²/s to 8.5 mm²/s, 6.5 mm²/s to 8.5 mm²/s, 7 mm²/s to 8.5 mm²/s, 7.5 mm²/s to 8.5 mm²/s, 8 mm²/s to 8.5 mm²/s, 0.5 mm²/s to 8 mm²/s, 0.5 mm²/s to 7.5 mm²/s, 0.5 mm²/s to 7 mm²/s, 0.5 mm²/s to 6.5 mm²/s, 0.5 mm²/s to 6 mm²/s, 0.5 mm²/s to 5.5 mm²/s, 0.5 mm²/s to 5 mm²/s, 0.5 mm²/s to 4.5 mm²/s, 0.5 mm²/s to 4 mm²/s, 0.5 mm²/s to 3.5 mm²/s, 0.5 mm²/s to 3 mm²/s, 0.5 mm²/s to 2.5 mm²/s, 0.5 mm²/s to 2 mm²/s, 0.5 mm²/s to 1.5 mm²/s, or 0.5 mm²/s to 1 mm²/s.

In some embodiments, the laser used in ablating step 104 is applied in cycles of 1 s to 1000 s, or any range or subrange between 1 s and 1000 s. For example, in some embodiments, the laser is applied in cycles of 48 s to 798 s, or any range or subrange of 48 c to 798 s. For example, in some embodiments, the laser is applied in cycles of 50 s to 798 s, 100 s to 798 s, 150 s to 798 s, 200 s to 798 s, 250 s to 798 s, 300 s to 798 s, 350 s to 798 s, 400 s to 798 s, 450 s to 798 s, 500 s to 798 s, 550 s to 798 s, 600 s to 798 s, 650 s to 798 s, 700 s to 798 s, 750 s to 798 s, 48 s to 750 s, 48 s to 700 s, 48 s to 650 s, 48 s to 600 s, 48 s to 550 s, 48 s to 500 s, 48 s to 450 s, 48 s to 400 s, 48 s to 350 s, 48 s to 300 s, 48 s to 250 s, 48 s to 200 s 48 s to 150 s, 48 s to 100 s, or 48 s to 500 s.

In some embodiments, the distance across one or more exposed portions of the substrate spans a distance of at least 0.5 mm. For example, in some embodiments, distance across the one or more exposed portions of the substrate span distances of at least 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm. In some embodiments, the one or more exposed portions of the substrate span a distance of 0.5 mm to 10 mm, or any range or subrange between 0.5 mm and 10 mm. In some embodiments, the one or more exposed portions of the substrate span a distance of 0.5 mm to 9 mm, 0.5 mm to 8 mm, 0.5 mm to 7 mm, 0.5 mm to 6 mm, 0.5 mm to 5 mm, 0.5 mm to 4 mm, 0.5 mm to 3 mm, 0.5 mm to 2 mm, 0.5 mm to 1 mm, 1 mm to 10 mm, 2 mm to 10 mm, 3 mm to 10 mm, 4 mm to 10 mm, 5 mm to 10 mm, 6 mm to 10 mm, 7 mm to 10 mm, 8 mm to 10 mm, or 9 mm to 10 mm.

At step 106, in some embodiments, the method includes forming an electrostatic chuck. In some embodiments, forming an electrostatic chuck includes contacting the substrate with an insulator layer. In some embodiments, forming an electrostatic chuck includes bonding the substrate to the insulator layer. In some embodiments, forming an electrostatic chuck includes adhering the substrate to the insulator layer. In some embodiments, the forming includes assembling one or more layers into an electrostatic chuck. In some embodiments, forming an electrostatic chuck comprising at least one of an ablated etch resistant layer, a dielectric layer, an ablated metallized layer, a bonding layer, an insulator layer, or any combination thereof. In some embodiments, the dielectric layer is located between the ablated etch resistant layer and the ablated metallized layer. In some embodiments, the ablated metallized layer is located between the dielectric layer and the bonding layer. In some embodiments, the bonding layer is located between the ablated metallized layer and the insulator layer. In some embodiments, the dielectric layer directly contacts the ablated etch resistant layer. In some embodiments, the dielectric layer directly contacts the metallized layer. In some embodiments, the dielectric layer directly contacts the bonding layer. In some embodiments, the bonding layer directly contacts the metallized layer. In some embodiments, the bonding layer directly contacts the insulator layer.

In some embodiments, when measuring an electrical resistance across the one or more exposed portions of the substrate formed between two metallized portions by laser ablation, the electrostatic chuck displays an electrical isolation of 300 GΩ to 1 TΩ, or any range or subrange between 300 GΩ and 1 Th. In some embodiments, when measuring an electrical resistance across the one or more exposed portions of the substrate, the electrostatic chuck displays an electrical isolation of 300 GΩ or more. In some embodiments, the electrostatic chuck displays an electrical isolation of 400 GΩ or more. In some embodiments, the electrostatic chuck displays an electrical isolation of 500 GΩ or more. In some embodiments, the electrostatic chuck displays an electrical isolation of 600 GΩ or more. In some embodiments, the electrostatic chuck displays an electrical isolation of 700 GΩ or more. In some embodiments, the electrostatic chuck displays an electrical isolation of 800 GΩ or more. In some embodiments, the electrostatic chuck displays an electrical isolation of 900 GΩ or more. In some embodiments, the electrostatic chuck displays an electrical isolation of 1 TΩ or more.

In some embodiments, a surface roughness on the one or more exposed portions of the substrate is less than 1 μm (e.g., 0.01 μm to 1 μm, or any range or subrange between 0.01 μm and 1 μm), or less than 0.75 micrometers. For example, in some embodiments, the expected surface roughness of the one or more exposed portions of the substrate is less than 0.7 μm, less than 0.65 μm, less than 0.6 μm, less than 0.55 μm, less than 0.51 μm, or less than 0.5 μm. In some embodiments,

In some embodiments, the one or more exposed portions of the substrate provide for a plurality of embossments.

In some embodiments, the one or more exposed portions of the substrate provide for a plurality of electrodes. In some embodiments, the plurality of electrodes includes separate electrically conducting pathways. In some embodiments, the plurality of electrodes includes at least two electrodes. In some embodiments, the plurality of electrodes includes at least three electrodes. In some embodiments, the plurality of electrodes includes at least four electrodes. In some embodiments, the plurality of electrodes includes at least five electrodes. In some embodiments, the plurality of electrodes includes at least six electrodes.

In some embodiments, the plurality of electrodes forms a pattern. In some embodiments, the pattern can be a pattern in which each of the plurality of electrodes extends from a starting point to an ending point. In some embodiments, the pattern is a pattern such that none of the plurality of electrodes contact or cross one another. In some embodiments, the pattern can be based on a shape of the surface substrate, such as a circular, square, or rectangular shape. In some embodiments, the plurality of electrodes forms a spiral pattern.

Some embodiments of this disclosure provide for an electrostatic chuck. In some embodiments, the electrostatic chuck includes a substrate having at least one etch resistant coating layer as disclosed herein. In some embodiments, the at least one etch resistant coating layer includes a laser ablated pattern. In some embodiments, the laser ablated pattern includes one or more exposed portions of the substrate spanning distances of at least 0.5 mm. For example, in some embodiments, the one or more exposed portions of the substrate in the laser ablated pattern span distances of at least 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm. It will be appreciated that the electrostatic chucks may comprise any of the electrostatic chucks disclosed herein, including those formed according to the methods disclosed herein, without departing from the scope of this disclosure.

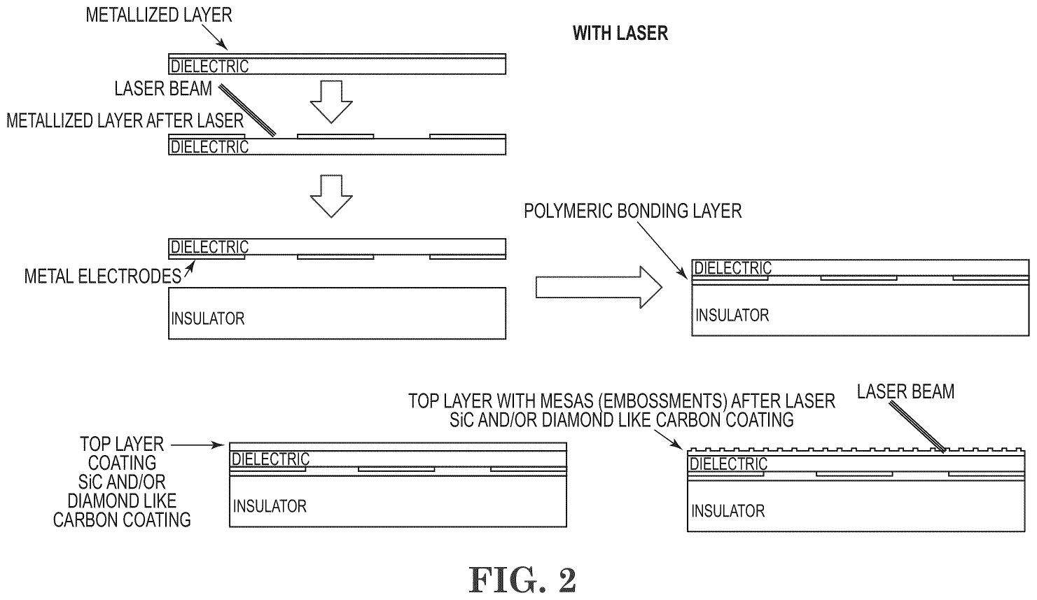

FIG. 2 is a schematic diagram of a method of forming an electrostatic chuck, according to some embodiments. As shown in FIG. 2, the metallized layer is located on the dielectric layer prior to laser-ablating the metallized layer. After laser-ablating the metallized layer, the laser-ablated metallized layer is bonded to an insulator layer via a polymeric bonding layer. An etch resistant layer is formed on an opposing surface of the dielectric layer and subsequently laser ablated to form embossments, wherein the opposing surface of the dielectric layer is the surface opposite the surface on which the laser-ablated metallized layer is located.

### Example

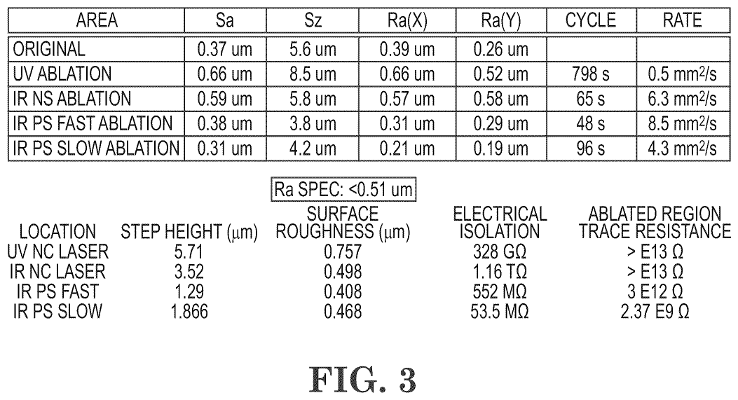

As an alternative to photolithography and/or etching, a metallized layer was removed by laser ablation. The metallized layer was located on an alumina substrate. A portion of the metallized layer was removed by laser ablation sufficient to expose at least a portion of the alumina substrate. The metallized layer comprised a titanium coating. UV nanosecond, IR nanosecond, and IR picosecond lasers were employed. Various attributes of the laser ablated samples were evaluated and compare (e.g. step height, surfacer roughness, electrical isolation, trace and resistance). The results are provided in FIG. 3 which includes two tables summarizing the test results of laser-ablated samples provided in accordance with some embodiments of the disclosure. In sum, samples ablated using the IR nanosecond and UV nanosecond lasers both passed electrical testing. The samples ablated using IR picosecond fast and slow exhibited favorable surface roughness values.

### Aspects

Various Aspects are described below. It is to be understood that any one or more of the features recited in the following Aspect(s) can be combined with any one or more other Aspect(s).
Aspect 1. A method, comprising:
   obtaining a substrate comprising an etch resistant coating layer;
   ablating, with a laser, the etch resistant coating layer so as to remove at least a portion of the etch resistant coating layer so as to provide one or more exposed portions of the substrate; and forming an electrostatic chuck,
      wherein, when measuring an electrical resistance across the one or more exposed portions of the substrate, the electrostatic chuck displays an electrical isolation of 300 GΩ or more.
Aspect 2. The method according to Aspect 1, wherein the etch resistant coating layer comprises silicon, carbide, yttrium oxide, aluminum oxide, or any combinations thereof.
Aspect 3. The method according to any one of Aspects 1-2, wherein the substrate comprises ceramic, alumina, zirconia, aluminum-nitride, aluminum-oxy-nitride, silicon-nitride, silicon-oxide, silicon-carbide, silicon-oxy-nitride, silicon-carbo-nitride, tungsten-carbide, molybdenum-disilicide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combinations thereof.
Aspect 4. The method according to any one of Aspects 1-3, wherein the laser comprises ultra-violet nanosecond (UV ns) lasers, infra-red nanosecond (IR ns) lasers, infra-red picosecond (IR ps) lasers, green lasers, or any combinations thereof.
Aspect 5. The method according to any one of Aspects 1-4, wherein the laser is applied at a rate of 0.5 mm²/s to 8.5 mm²/s.
Aspect 6. The method according to any one of Aspects 1-5, wherein the laser is applied in cycles of 48 s to 798 s.
Aspect 7. The method according to any one of Aspects 1-6, wherein the one or more exposed portions of the substrate span distances of at least 0.5 mm.
Aspect 8. The method according to any one of Aspects 1-7, wherein the one or more exposed portions of the substrate provide for a plurality of embossments.
Aspect 9. A method, comprising:
   obtaining a substrate comprising a metallized layer;
   ablating, with a laser, the metallized layer so as to remove at least a portion of the metallized layer so as to provide one or more exposed portions of the substrate; and
   forming an electrostatic chuck,
      wherein, when measuring an electrical resistance across the one or more exposed portions of the substrate, the electrostatic chuck displays an electrical isolation of 300 GΩ or more.
Aspect 10. The method according to Aspect 9, wherein the metallized layer comprises aluminum, tungsten, nickel, stainless steel, silver, gold, tantalum, platinum, palladium, cobalt, titanium, copper, molybdenum, silicon, or any combinations thereof.
Aspect 11. The method according to any one of Aspects 9-10, wherein the metallized layer has a thickness of 0.7 micrometers to 1.5 micrometers.
Aspect 12. The method according to any one of Aspects 9-11, wherein the one or more exposed portions of the substrate span distances of at least 0.5 mm.
Aspect 13. The method according to any one of Aspects 9-12, wherein the one or more exposed portions of the substrate provide for a plurality of electrodes having separate electrically conducting pathways.
Aspect 14. An electrostatic chuck, comprising:
   a substrate having at least one etch resistant coating layer comprising a laser ablated pattern;
      wherein the laser ablated pattern comprises one or more exposed portions of the substrate spanning distances of at least 0.5 mm.
Aspect 15. The electrostatic chuck according to Aspect 14, wherein the at least one etch resistant coating layer comprises a metallized layer.
Aspect 16. The electrostatic chuck according to any one of Aspects 14-15, wherein the one or more exposed portions of the substrate provide for a plurality of electrodes having separate electrically conducting pathways.
Aspect 17. The electrostatic chuck according to Aspect 16, wherein the one or more exposed portions of the substrate provide for a plurality of embossments.

It is to be understood that changes may be made in detail, especially in matters of the construction materials employed and the shape, size, and arrangement of parts without departing from the scope of this disclosure. This Specification and the embodiments described are examples, with the true scope and spirit of the disclosure being indicated by the claims that follow.

What is claimed is:

1. A method, comprising:
obtaining a substrate comprising an etch resistant coating layer;
ablating, with a laser, the etch resistant coating layer to remove at least a portion of the etch resistant coating layer and obtain one or more exposed portions of the substrate; and
forming an electrostatic chuck,
wherein, when measuring an electrical resistance across an exposed portion of the substrate between two metallized portions, the electrostatic chuck exhibits an electrical isolation of 300 GΩ or more.

2. The method of claim 1, wherein the etch resistant coating layer comprises silicon, carbide, yttrium oxide, aluminum oxide, or any combinations thereof.

3. The method of claim 1, wherein the substrate comprises ceramic, alumina, zirconia, aluminum-nitride, aluminum-oxy-nitride, silicon-nitride, silicon-oxide, silicon-carbide, silicon-oxy-nitride, silicon-carbo-nitride, tungsten-carbide, molybdenum-disilicide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combinations thereof.

4. The method of claim 1, wherein the laser comprises ultra-violet nanosecond (UV ns) lasers, infra-red nanosecond (IR ns) lasers, infra-red picosecond (IR ps) lasers, green lasers, or any combinations thereof.

5. The method of claim 1, wherein the laser is applied at a rate of 0.5 mm²/s to 8.5 mm²/s.

6. The method of claim 1, wherein the laser is applied in cycles of 48 s to 798 s.

7. The method of claim 1, wherein the one or more exposed portions of the substrate span distances of at least 0.5 mm.

8. The method of claim 1, wherein the one or more exposed portions of the substrate provide for a plurality of embossments.

9. A method, comprising:
obtaining a substrate comprising a metallized layer;
ablating, with a laser, the metallized layer so as to remove at least a portion of the metallized layer so as to provide one or more exposed portions of the substrate; and
forming an electrostatic chuck,
wherein, when measuring an electrical resistance across an exposed portion of the substrate between two metallized portions, the electrostatic chuck exhibits an electrical isolation of 300 GΩ or more.

10. The method of claim 9, wherein the metallized layer comprises aluminum, tungsten, nickel, stainless steel, silver, gold, tantalum, platinum, palladium, cobalt, titanium, copper, molybdenum, silicon, or any combinations thereof.

11. The method of claim 9, wherein the metallized layer has a thickness of 0.7 micrometers to 1.5 micrometers.

12. The method of claim 9, wherein the one or more exposed portions of the substrate span distances of at least 0.5 mm.

13. The method of claim 9, wherein the one or more exposed portions of the substrate provide for a plurality of electrodes having separate electrically conducting pathways.

14. An electrostatic chuck, comprising:
a substrate having at least one etch resistant coating layer comprising a laser ablated pattern comprising one or more exposed portions of the substrate spanning distances of at least 0.5 mm, wherein when measuring an electrical resistance across an exposed portion of the substrate between two metallized portions, the electrostatic chuck exhibits an electrical isolation of 300 GΩ or more.

15. The electrostatic chuck of claim 14, wherein the at least one etch resistant coating layer comprises a metallized layer.

16. The electrostatic chuck of claim 14, wherein the one or more exposed portions of the substrate provide for a plurality of electrodes having separate electrically conducting pathways.

17. The electrostatic chuck of claim 14, wherein the one or more exposed portions of the substrate provide for a plurality of embossments.
